(19) United States
(12) Patent Application Publication
(10) Pub. No.: US 2007/0040195 A1
(43) Pub. Date: Feb. 22, 2007

(54) Monolithic integrated passive and active electronic devices with biocompatible coatings

(75) Inventor: Orlando Auciello, Bolingbrook, IL (US)

Correspondence Address: HARRY M. LEVY;EMRICH & DITHMAR, LLC, 125 SOUTH WACKER DRIVE, SUITE 2080, CHICAGO, IL, 60606-4401, US

(73) Assignee: The University of Chicago, Chicago, IL (US)

(21) Appl. No.: 11/207,379

(22) Filed: Aug. 19, 2005

(51) Int. Cl. H01L 29/94; H01L 29/76; H01L 31/00

(52) U.S. Cl. 257/295

(57) ABSTRACT

A bio-compatible electrical element including a high-dielectric amorphous TiₓAl₁₋ₓO_{y} oxide alloy wherein a TiO₂ layer is between the bio-compatible electrical element and a biological such as human environment. A continuous and substantially pinhole free dielectric amorphous TiₓAl₁₋ₓO_{y} oxide alloy wherein x is in the range of from about 0.5 to about 0.7 and y is in the range of about 2 to about 3 and having a TiO₂ layer exterior thereto formed into a passive element such as a capacitor or an active element such as a microchip is disclosed.

### CONTRACTUAL ORIGIN OF THE INVENTION

The United States Government has rights in this invention pursuant to Contract No. W-31-109-ENG-38 between the U.S. Department of Energy and The University of Chicago representing Argonne National Laboratory.

### FIELD OF THE INVENTION

This invention relates to thin film-based devices containing high dielectric oxide layers in both passive and active devices having a biocompatible coating for implantation in warm bloodied animals, particularly human. My previous applications relating to this matter disclosed high dielectric alloy oxides, U.S. application Ser. No. 10/351,826 filed Jan. 27, 2003 and thin film based devices in U.S. application Ser. No. 11/073,263 filed Mar. 3, 2005, the entire disclosures of which are incorporated herein. Complex oxide film-based devices have many uses such as non-volatile ferroelectric random access memories (FeRAMs), dynamic random access memories (DRAMs), high frequency devices, input/output capacitors for integrated circuits and many other devices. Many of these devices have uses in the fabrication of monolithically integrated microprocessors, implantable in animals and humans, providing a biocompatible a coating is used.

### BACKGROUND OF THE INVENTION

A wide variety of devices are being developed for use in humans by way of implantation, both passive devices such as capacitors and active devices such as microchips. Miniaturized microprocessors are useful when provided with biocompatible exterior surfaces. Of particular importance are devices incorporating both high dielectric and biocompatible properties.

This invention relates to the integration of materials based on thin film technology to enable the integration of passive devices (e.g., capacitors) with active microelectronic devices (e.g. microchip, thin film-based batteries) in a monolithic microprocessor with biocompatible capability for bioimplantable or generic microdevices, respectively. The technology described here includes the integration of electrically conductive layers with high-dielectric constant films for the fabrication of monolithically integrated microdevices with bioinert/biocompatible protective layers to produce human or animal implantable bioinert/biocompatible or generic microchips/microprocessors, respectively.

The multilayers are produced in integrated cycles by chemical vapor deposition methods (e.g., metalorganic chemical vapor-deposition (MOCVD) or atomic layer deposition (ALD)) that are suitable for film growth on high aspect ratio structures and for hermetic coating deposition for encapsulation of microchips to make them biocompatible if necessary. The deposition methods can be implemented at relatively low temperatures (≦400° C.), which make them suitable for production of heterostructured thin films in an integrated manner for fabrication of integrated electronic or magnetic passive/active devices within the thermal budget required (≦400° C.) by CMOS technology.

The electrically conductive layers for integrated thin film-based capacitors or other passive devices and for active devices, i.e. batteries, can be produced with metals (e.g., Pt, Cu, Au, Al, W, Ru or any other metal suitable for MOCVD or ALD deposition) or conductive metal oxides (e.g., RuO₂, SrRuO₃, La—Sr—Co—O, or any other good conductor metal-oxide).

The high-k dielectric layers can be of any of the existing high-k dielectric materials (e.g. crystalline BaSrₓTi₁₋ₓO₃, BaTiO₃, SrTiO₃, amorphous intermediate dielectric materials (e.g. HfO₂, ZrO₂, TixAl₁₋ₓO_{y} alloys), or new crystalline high-k dielectric materials without Pb (e.g., Bismuth Ferrites (BFO)) or to be discovered materials that provide high dielectric constant, high capacitance, low leakage current, and high dielectric breakdown.

The materials for thin film batteries can include any of the materials currently used as electrode layers in thin film based batteries (e.g., Cu, CuSn alloys, etc.) or new materials (e.g. novel CuLi alloy electrodes developed by us at ANL and under investigation for the development of high-efficiency thin film-based batteries).

Although MOCVD and ALD are the main techniques described herein, if required and as appropriate, other techniques such as room temperature or high temperature (300-700° C.) physical vapor deposition of spin-on sol-gel methods can also be used for producing the appropriate layers, the high temperature layers used whenever thermal budgets of the proposed devices allow it.

### SUMMARY OF THE INVENTION

Accordingly, it is an important object of the present invention to provide electric elements incorporating a high dielectric amorphous TiAl oxide alloy which is biocompatible with a biological environment.

Another object of the present invention is to provide a high-dielectric amorphous TiₓAl₁₋ₓO_{y} oxide alloy wherein a TiO₂ layer is between said biocompatible electrical element and a biological environment.

Still another object of the present invention is to provide a biocompatible electrical element including a continuous and substantially pinhole free dielectric amorphous TiₓAl₁₋ₓO_{y} oxide alloy wherein x is in the range of from about 0.5 to about 0.7 and y is between about 2 and about 3 and having a TiO₂ biocompatible layer exterior thereto between the biocompatible electrical element and a biological environment.

Still another object of the invention is to provide a biocompatible electrical capacitor including a high-dielectric amorphous TiₓAl₁₋ₓO_{y} layer or BST or SrBiTaO with a TiO₂ layer between the biocompatible electrical capacitor and a biological environment.

Still another object of the invention is to provide a TiₓAl₁₋ₓO_{y} layer as a capacitive oxide layer for gates in complementary metal oxide semiconductor (CMOS) devices.

Still another object of this invention is to provide a micro or nano battery based on high performance solid electrolytes integrated with high performance electrodes (e.g. cubic or Cu Su alloys and lipon).

The invention consists of certain novel features and a combination of parts hereinafter fully described, illustrated in the accompanying drawings, and particularly pointed out in the appended claims, it being understood that various changes in the details may be made without departing from the spirit, or sacrificing any of the advantages of the present invention.

### BRIEF DESCRIPTION OF THE DRAWINGS

For the purpose of facilitating an understanding of the invention, there is illustrated in the accompanying drawings a preferred embodiment thereof, from an inspection of which, when considered in connection with the following description, the invention, its construction and operation, and many of its advantages should be readily understood and appreciated.

FIG. 1 is a schematic representation of the electrical equivalent circuit for thin film-based input/output coupling capacitor integrated with a microprocessor (microchip);

FIG. 2 is schematic representation of a thin film based battery coated with a TiₓAl₁₋ₓO_{y}/TiO₂ layer for biocompatible applications.

FIG. 3 is a schematic representation of a metalorganic chemical vapor deposition (MOCVD) reactor with a liquid delivery system;

FIGS. 4(a) and (b) are graphs showing the relationship between permittivity and applied bias voltage for a 890 Å BST film and a 2224 Å BST film;

FIG. 5 is a schematic representation of an atomic layer deposition device using a nitrogen source for two separate samples at 46 cycles and 108 cycles; and

FIG. 6 is a schematic representation of surface chemistry for the atomic layer deposition of aluminum oxide via alternate treatments of trimethyl aluminum and water.

While the invention has been particularly shown and described with reference to a preferred embodiment hereof, it will be understood by those skilled in the art that several changes in form and detail may be made without departing from the spirit and scope of the invention.

### DESCRIPTION OF THE PREFERRED EMBODIMENT

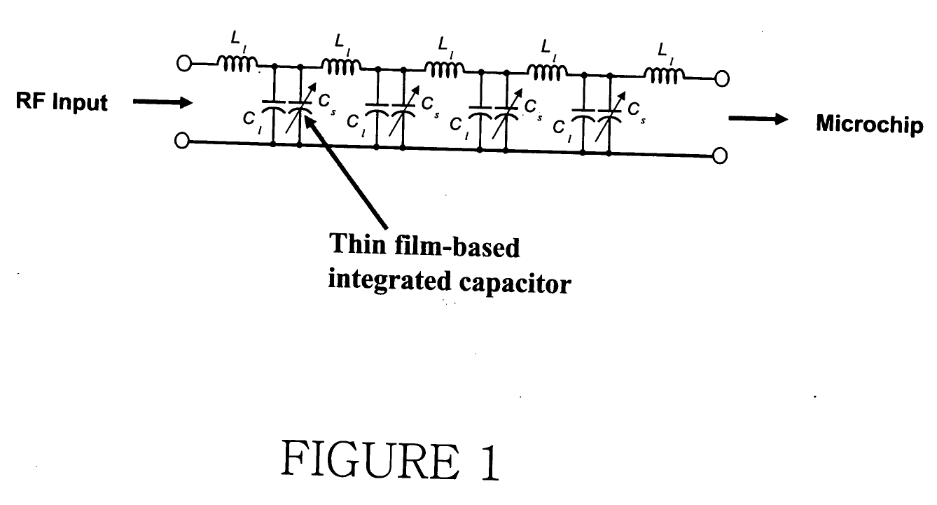

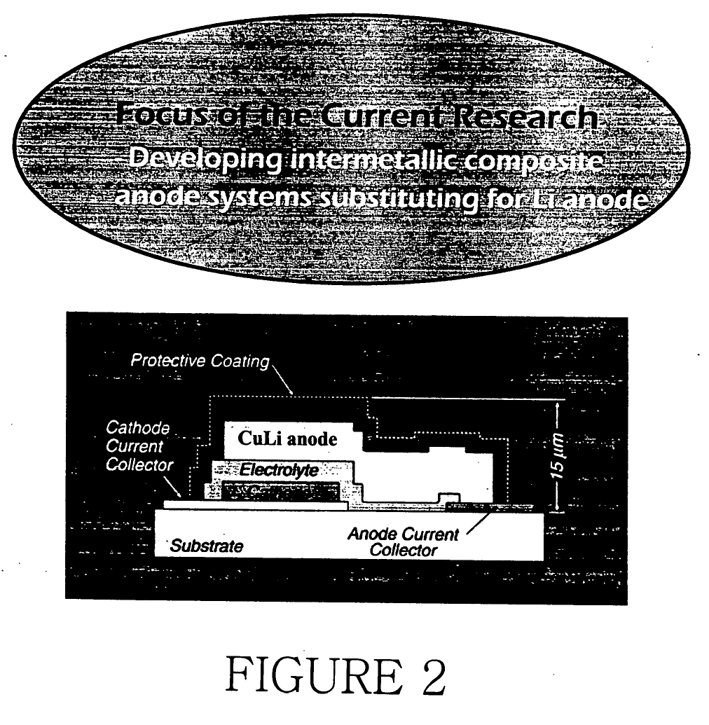

Referring to FIG. 1, there is shown a thin film-based integrated capacitor of the type described previously in the aforementioned Auciello applications and also described in the Schulman et al. U.S. Pat. No. 6,043,437 issued Mar. 28, 2000 and the Schulman et al. publication no. US 2003/0087197 A1, the disclosures, both of which are incorporated herein by reference. Capacitors of the type illustrated in FIG. 1 are frequently used in combination with microchips as illustrated in FIG. 1 and operatively connected to thin film-based batteries as illustrated in FIG. 2 in order to provide implantable devices in animals and human beings, which as previously discussed, is an important aspect of the present invention. One of the principle applications is in the artificial retina program, a substantial amount of work towards which is being provided at Argonne National Laboratory in which a Si-based microchip including monolithically integrated input/output coupler capacitor need to be coated by a biocompatible TiₓAl₁₋ₓO_{y}/TiO₂ layer or single TiO₂ layer for implantation into the human retina to restore sight to people blinded by retina degeneration.

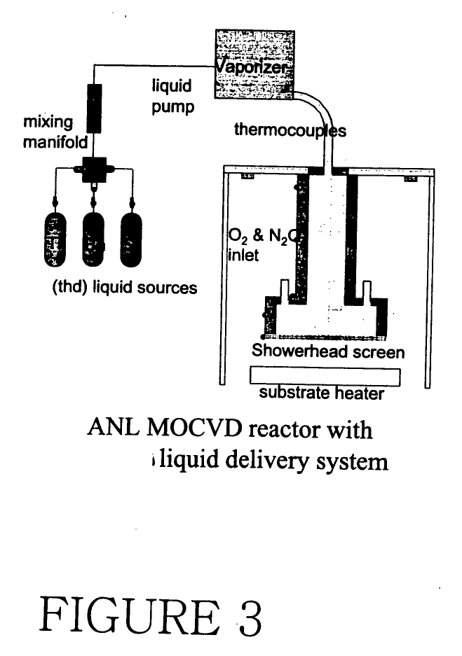

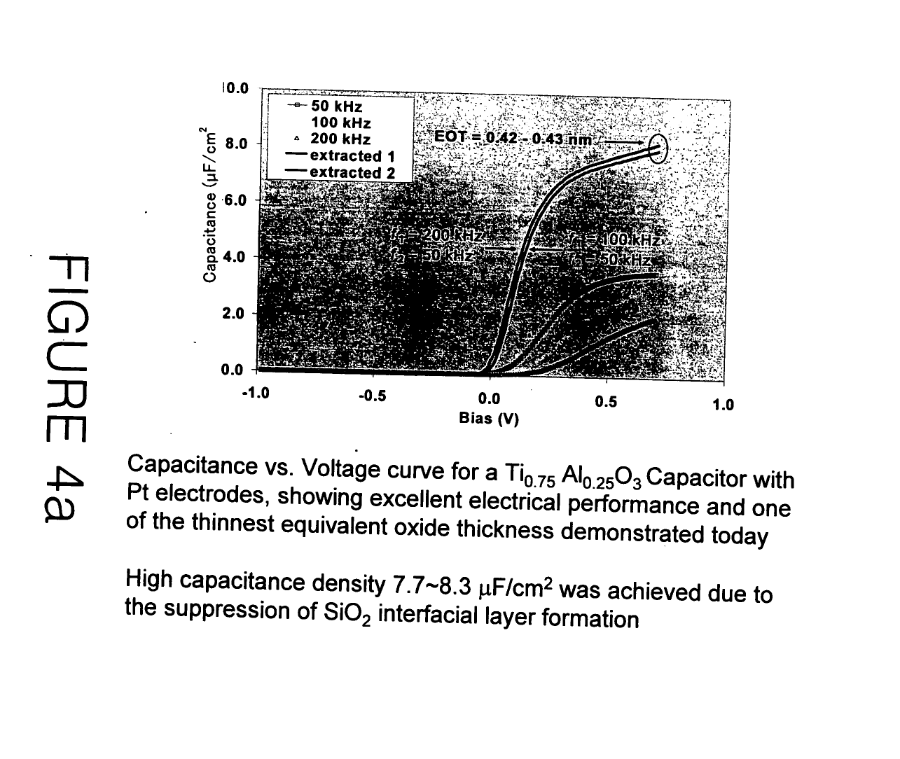

Referring to FIG. 3, there is illustrated a schematic diagram for producing thin film based capacitors such as barium strontium titanate (BST) capacitors using the Argonne National Laboratory MOCVD reactor with a liquid delivery system. As indicated in the drawing, liquid sources for titanium, barium and stronthium which lead to a mixing manifold that are pumped via a liquid pump to a vaporizer and thence into the reactor chamber, all as is well known in the art and they can also be used to deposit biocompatible TiₓAl₁₋ₓO_{y}/TiO₂ or Ti and TiO₂ oxide layers.

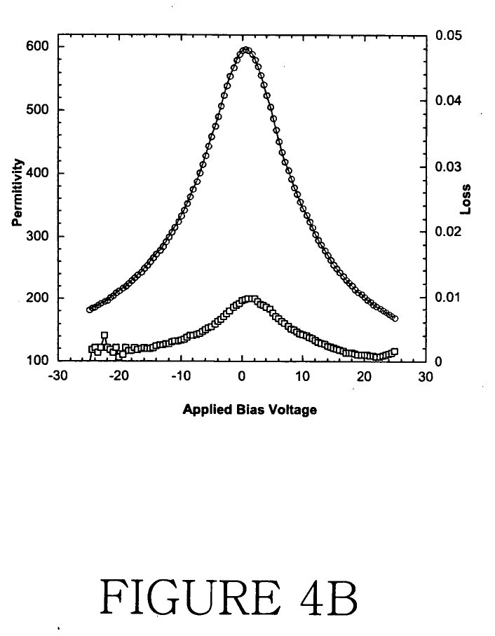

The sample shown in FIG. 4a relates to a Ba_{0.70}Sr_{0.30}TiO₃ film grown by metalorganic chemical vapor deposition (MOCVD) using metalorganic precursors of Ba(thd)₂, Sr(thd)₂, and Ti (O-iPr)₂-(thd)₂ with polyamine adducts introduced using high purity nitrogen as a carrier gas into the MOCVD reactor, via a temperature-controlled flash-vaporizer and a computer-controlled liquid delivery system (ATMI LDS-300B) that provided good composition control and reproducibility of the delivered precursor mixture. The temperatures of the delivery lines were controlled to avoid condensation or premature reaction of the precursors prior to introduction into the MOCVD reactor. The precursors were thoroughly mixed with high purity reactive gases (0₂ and N₂) in a showerhead (FIG. 3) designed to provide deposition of BST films with uniform composition and thickness over large area substrates. The (Ba+Sr)/Ti ratios were varied between 0.96 and 1.05 while the Ba/Sr ratio of the BST thin films was kept at 70/30. The film deposition and processing conditions are summarized in Table I.

TABLE 1

| | |
|---|---|
| Substrates | Pt(1000 Å) SiO₂(1000 Å)/Si |
| Substrate heater temperature: | 650° C. |
| Reactive gases: | O₂ and N₂O |
| Reactive gas flow rate: | 250-1000 SCCM |
| Reactor pressure: | 1.5-2.7 Torr |
| Top electrodes: | e-beam evaporated Pt (1000 Å) |
| Post electrode anneal: | 550° C. for 0.5 hrs. |
| Electrical characterization: | HP4192A at 1 MHz and 0.1 V rms |

The sample corresponding to FIG. 4b relates to a film of Ti_{0.75}Ai_{0.35}0x grown using ion beam sputter deposition, where an ion beam of 3 cm diameter made of Ar ions of 500 eV and 20 mA of current impacted a metallic alloy target with Ti_{0.75}Al_{0.35} composition. The sputtered flux was deposited on a Si substrate at room temperature until a film about 3 nm thick was grown. Subsequently, an atomic oxygen beam was directed at the Ti_{0.75}Al_{0.35} and the film was fully oxidized at room temperature resulting in an amorphous TAO layer with a large capacitance density (˜7-8 μF/cm²) and leakage current 10⁴-10⁵ times lower than for an equivalent capacitor based on a SiO₂ layer.

Referring to FIGS. 4a and 4b, the capacitor structure shown in FIG. 4C is used to test the capacitance behavior of the dielectric films with the top and bottom electrodes. The comparison of the permittivity of BST films with 890 and 2224 Å indicates that as the film thickness increases the dielectric behavior of the capacitor approaches that of a bulk BST capacitor material, i.e., exhibit larger permittivity, thus capacitance that the thinner film, because for capacitors with thicker layers approach the behavior of capacitors made of bulk material.

Similarly, a BaSrₓTi₁₋ₓO₃ dielectric/Ni electrodes can provide a 3.8 μF/cm² capacitance. BaTiO₃ dielectric about 600 nm thick/Cu with low PO₂ can provide (5 μF/cm²-1 layer capacitor with φ=0.5 cm), which is in the parameter requirements which falls within the parameter requirements for the artificial retinal microchip.

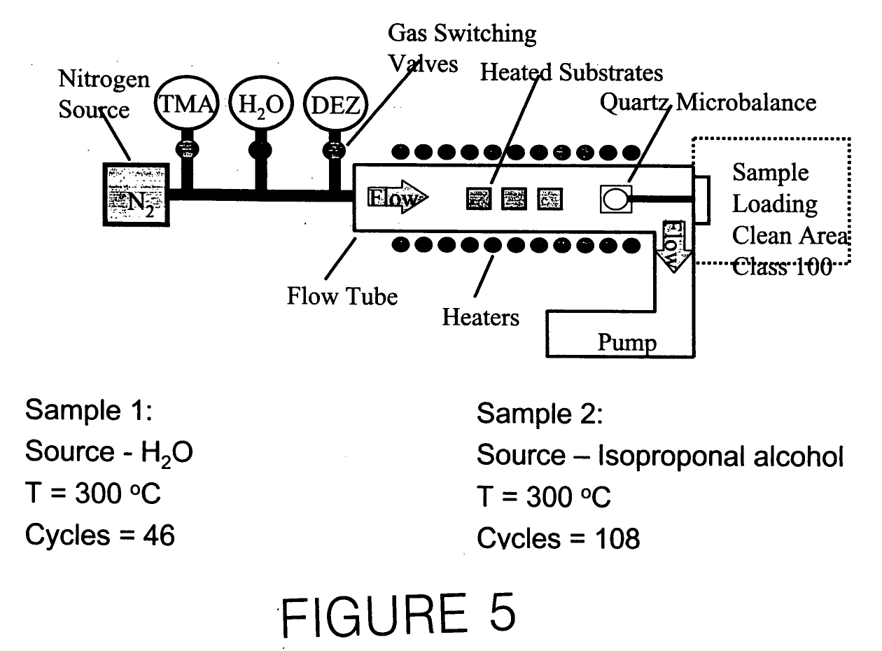

As stated above, the two principal methods for producing the layers forming the present invention are MOCVD and ALD, although sputter-deposition and laser ablation can also be used. FIG. 5 shows a schematic diagram for depositing TiAl layers by ALD. ALD is a well known method in the art and FIG. 5 is included simply for purposes of completeness, it being understood by one of ordinary skill in the art is well aware how to deposit the layers of the present invention both by MOCVD and ALD techniques. As illustrated in FIG. 5, the gas source can be nitrogen as is well known in the art. Other inert gases and water or other vaporized material can be used such as isoproponal alcohol. In all other respects, the apparatus is known in the art.

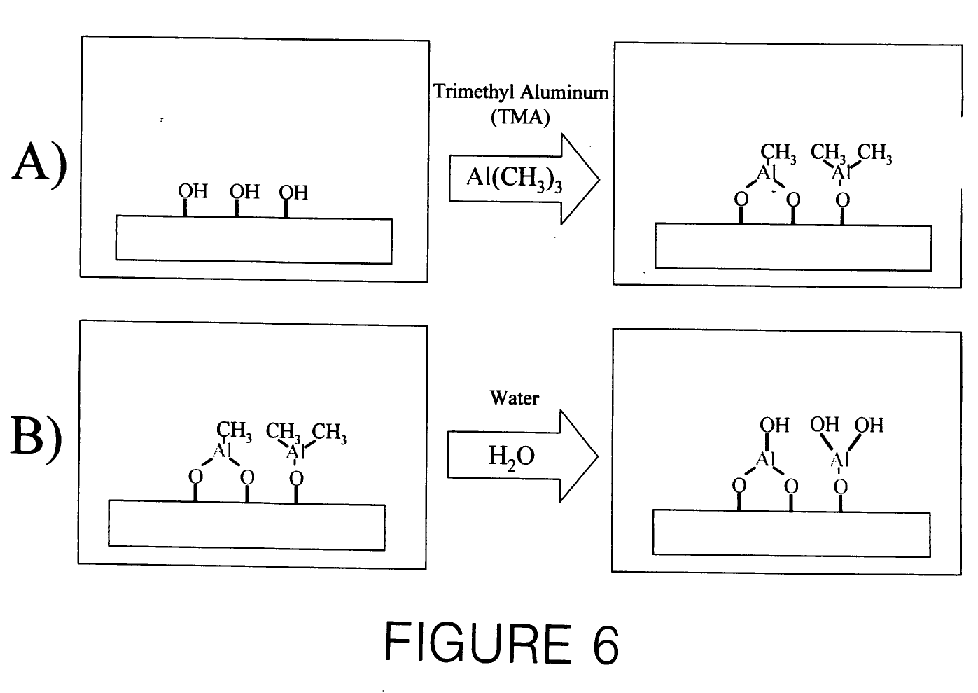

FIG. 6 shows the mechanism by which Al₂O₃ is laid down from trimethyl aluminum (TMA) in the ALD process which is a surface chemistry reaction using water to provide the OH groups necessary as the reactive moiety. Again, the mechanism by which ALD operates is well known and is understood by one of ordinary skill in the art.

To the layer of a Al₂O₃, TiO₂ layer is added in between the biological environment and the electrical device. The process would be:

1. expose the substrate surface to OH precursors as indicated on the top left FIG. 6.

2. expose the substrate to Al(CH₃)₂ precursors flowing as a gas. Some hydrogen from the precursor react with H from the OH molecule deposited on the surface in the prior step and for H₂ volatile species. Al atoms bind chemically to the O and CH species remain on top as indicated on the top right figure.

3. flow again water molecules and produce another layer of OH as indicated on the bottom left figure.

4. flow the Ti (CH₃)₂ precursor and a TiO bond will be formed.

5. repeat all steps from 1-4 many times until a film with the desired thickness is produced.

By assembling and integrating materials described hereinbefore, monolithic integration of passive and active (microchip) or batteries devices for fabrication of microprocessors with bio-inert and/or biocompatible properties are available. This is particularly important in the artificial retina program which is in the process of developing integrated coupling capacitors for the I/O component of the retinal microchip. These materials in combination with thin film batteries will be introduced into a variety of small devices in the medical field as well as in other fields even these that do not include biocompatible environments. Because a biological environment such as that in the human body often involves saline solutions, it is frequently and extremely important to provide fully dense or hermetically sealed coatings which are biologically inert to the human body environment. Amorphous titanium aluminum oxide (TiₓAl₁₋ₓO_{y}) wherein x is in the range of from about 0.5 to about 0.7 and y is in the range of from about 2 to about 3 and amorphous and is a biologically inert material and even more so, when covered by an external TiO₂ layer. Moreover, when fully dense high dielectric amorphous titanium aluminum oxide alloy films have thicknesses in the range of from about 10 to about 100 Å then the film is continuous and substantially free of pinholes, a condition prerequisite for good protection from the biological environment. In general, thinner coatings are preferred such as about 30 Å, but they must be substantially pinhole free. In some instances, the titanium aluminum oxide alloy layer may be a coating and in other cases it may be otherwise applied either directly or indirectly but in all cases the amorphous oxide alloy must be intermediate between the biological environment and the electrical element.

Thin film micro or nano batteries based on high performance solid electrolytes now available for Cu or CuSn alloy electrodes and lithium or lithium containing materials and containing high dielectric materials which are biocompatible and coated with biocompatible materials, such as TiO₂ are important aspects of this invention.

While there has been disclosed what is considered to be the preferred embodiments of the present invention, it is understood that various changes in the details may be made without departing from the spirit, or sacrificing any of the advantages of the present invention.

The embodiments of the invention in which an exclusive property or privilege is claimed are defined as follows:

1. A bio-compatible electrical element including one or more of high-dielectric polycrystalline BaSrₓTi₁₋ₓO₃ (BST), Sr B₂ Ta₂ O₉ or an amorphous TiₓAl₁₋ₓO_{y} oxide alloy wherein a TiO₂ layer is between said bio-compatible electrical element and a biological environment.

2. The bio-compatible electrical element of claim 1, wherein said electrical element is an integrated capacitor fabricated on a semiconductor material.

3. The bio-compatible electrical element of claim 1, wherein said electrical element is a gate material in an integrated transistor fabricated on a semiconductor material.

4. The bio-compatible electrical element of claim 1, wherein said high-dielectric amorphous TiₓAl₁₋ₓO_{y} oxide alloy has a thickness less than about 100 Angstroms.

5. The bio-compatible electrical element of claim 1, wherein said high-dielectric amorphous TiₓAl₁₋ₓO_{y} oxide alloy has a thickness less than about 30 Angstroms.

6. The bio-compatible electrical element of claim 1, wherein said high-dielectric amorphous TiₓAl₁₋ₓO_{y} oxide alloy is continuous and substantially free of pinholes.

7. The bio-compatible electrical element of claim 1, wherein said high-dielectric amorphous TiₓAl₁₋ₓO_{y} oxide alloy is TiₓAl₁₋ₓO_{y} and said TiO₂ layer is on the surface thereof.

8. The bio-compatible electrical element of claim 1, wherein x is in the range of from about 0.5 to about 0.7 and y is in the range of about 2 to about 3.

9. A bio-compatible electrical element including a continuous and substantially pinhole free dielectric amorphous TiₓAl₁₋ₓO_{y} oxide alloy wherein x is in the range of from about 0.5 to about 0.7 and y is in the range of about 2 to about 3 and having a TiO₂ layer exterior thereto between said bio-compatible electrical element and a biological environment.

10. The bio-compatible electrical element of claim 9, wherein said high-dielectric amorphous TiₓAl₁₋ₓO_{y} oxide alloy has a thickness less than about 100 Angstroms.

11. A bio-compatible electrical capacitor including a high-dielectric amorphous TiₓAl₁₋ₓO_{y} layer with a TiO₂ layer between said bio-compatible electrical capacitor and a biological environment.

12. The bio-compatible electrical capacitor of claim 11, wherein the biological environment is a warm blooded animal.

13. The bio-compatible electrical capacitor of claim 12, wherein the biological environment is human.

14. The bio-compatible electrical capacitor of claim 12, wherein the oxide alloy coating is pinhole free.

15. The bio-compatible electrical capacitor of claim 15, wherein the capacitor contains a high dielectric material of BST and/or SrBi₂Ta₂O₉.

16. The biocompatible electrical element of claim 1, wherein said electrical element is an integrated capacitor on an insulator.

17. The biocompatible electrical element of claim 16, wherein said insulator is BST or Al₂O₃ or SrBi₂Ta₂O₉.

18. A biocompatible thin film battery comprising electrodes containing Cu or a CuSn alloy and lithium or a lithium containing material separated by a solid electrolyte encapsulated or separated from a biological environment by TiO₂ or a biologically compatible high dielectrical material such as an amorphous TiₓAl₁₋ₓO_{y} oxide alloy or a combination thereof.
